(19) United States
(12) Patent Application Publication
(10) Pub. No.: US 2010/0027231 A1
(43) Pub. Date: Feb. 4, 2010

(54) VIBRATION DAMPENING STRUCTURE FOR ELECTRONIC DEVICE

(75) Inventors: HUNG-CHIEH CHANG, Tu-Cheng (TW); LI-PING CHEN, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/265,632

(22) Filed: Nov. 5, 2008

(30) Foreign Application Priority Data
Jul. 30, 2008 (CN) 200820301632.1

(51) Int. Cl. F16F 7/00; H05K 7/12

(52) U.S. Cl. 361/807; 267/141

(57) ABSTRACT

An electronic device includes a chassis, an electronic element being fixed in the chassis, a mounting hole defined in a bottom edge of the electronic element, and a vibration dampening structure inserted in the mounting hole. A through hole is defined in a center portion of the vibration dampening structure, the vibration dampening structure including a first dampening portion and a second dampening portion and a fastener inserted in the through hole to fix the electronic element in the chassis. The fastener includes a head. The first dampening portion prevents the head of the fastener from contacting the bottom edge of the electronic element, and the second dampening portion preventing the bottom edge from contacting the chassis.

### BACKGROUND

1. Technical Field

The present invention relates to vibration dampening structures and, more particularly, to a vibration dampening structure for an electronic device.

2. Description of Related Art

Electronic devices, such as computers, usually include fan modules for cooling electronic elements in the electronic devices. Typically, fans will vibrate and produce noise when running, so it is important to stably secure the fans in the electronic devices.

There are many ways to secure fans in electronic devices. For example, fans may be secured in electronic devices with screws. However, screws directly contact both the fans and the electronic devices allowing transmission of vibrations from one to other.

What is needed, therefore, is a convenient simple vibration dampening structure for use in an electronic device.

### BRIEF DESCRIPTION OF THE DRAWINGS

FIG. 1 is an exploded, isometric view of one embodiment of a vibration dampening structure and a fan holder;

FIG. 2 is an isometric view of the vibration dampening structure of FIG. 1;

FIG. 3 is a cross-sectional view of the vibration dampening structure of FIG. 2, taken along line III-III;

FIG. 4 is a partially assembled view of the vibration dampening structure of FIG. 1, mounted on the fan holder; and

FIG. 5 is an assembled view of FIG. 1.

### DETAILED DESCRIPTION OF EMBODIMENTS

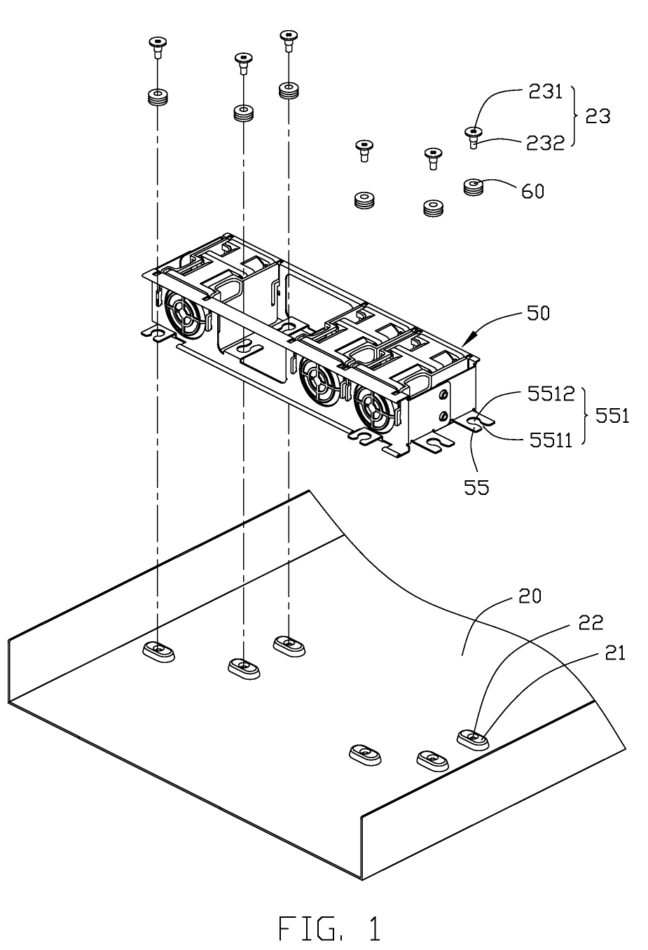

Referring to FIG. 1, a vibration dampening structure 60 is configured to mount on a fan holder 50 and be placed around a fastener 23. The fastener 23 includes a head 231 and a shank 232 extending perpendicularly from the head 231.

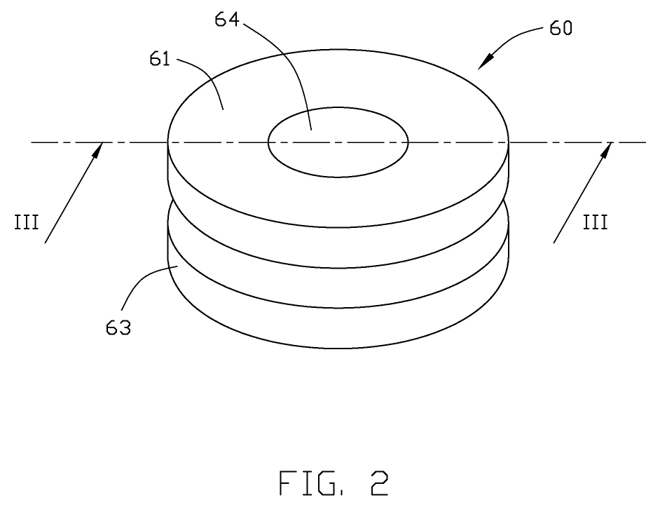

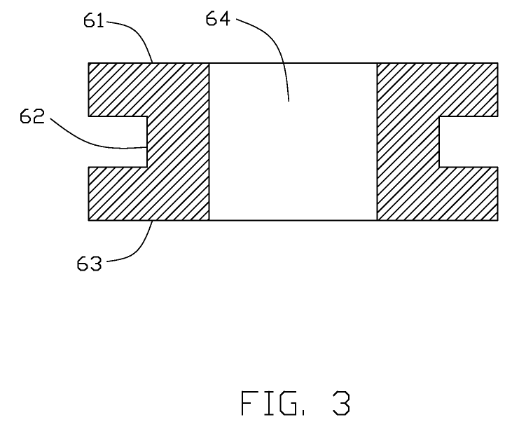

Referring also to FIGS. 2 and 3, the vibration dampening structure 60 is annular-shaped and made of a dampening material, such as rubber. The vibration dampening structure 60 includes a first dampening portion 61, a neck portion 62 connecting with the first dampening portion 61, a second dampening portion 63 connecting with the neck portion 62. A through hole 64 is defined in a center portion of the vibration dampening structure 60 and extending through the first dampening portion 61, the neck portion 62, and the second dampening portion 63.

A fixing piece 55 is formed on a bottom portion of the fan holder 50. A mounting hole 551 is defined in the fixing piece 55. The mounting hole 551 includes a guiding portion 5511 extending inward from an edge of the fixing piece 55 and a receiving portion 5512 connecting with the guiding portion 5511. The receiving portion 5512 may have a circular configuration. A width of the guiding portion 5511 is smaller than a diameter of the receiving portion 5512. The diameter of the receiving portion 5512 is smaller than outer diameters of the first and second dampening portions 61, 63. A thickness of the neck portion 62 is less than or equal to a thickness of the fixing piece 55.

A chassis 20 is configured to support the fan holder 50 to be mounted therein. A protrusion 21 is formed on the chassis 20. A hole 22 is defined in the protrusion 21 to receive the fastener 23.

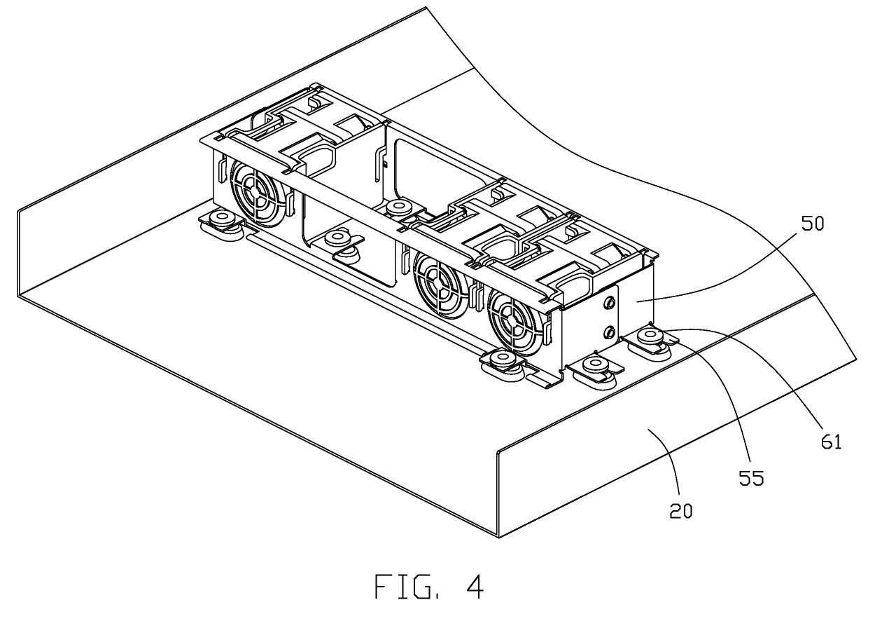

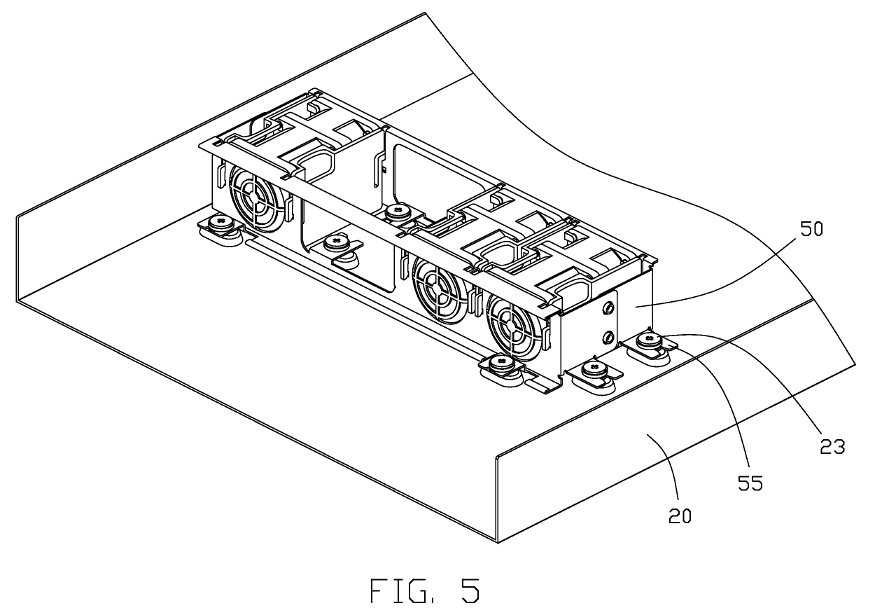

Referring to FIGS. 4 and 5, when the fan holder 50 is mounted on the chassis 20, the vibration dampening structure 60 is first secured in the fixing piece 55 of the fan holder 50. The neck portion 62 of the vibration dampening structure 60 slides into the receiving portion 5512 of the mounting hole 551 via the guiding portion 5511 of the mounting hole 551. The first dampening portion 61 contacts one side of the fixing piece 55 and the second dampening portion 63 contacts the other side of the fixing piece 55. Thus, the first and second dampening portions 61, 63 sandwich the fixing piece 55 therebetween. The shank 232 of the fastener 23 is inserted into the through hole 64 of the vibration dampening structure 60 and the hole 22 of the chassis 20 to mount the fan holder 50 onto the chassis 20.

The first dampening portion 61 prevents the head 231 of the fastener 23 from contacting the fixing piece 55. The second dampening portion 63 prevents the protrusion 21 of the chassis 20 from contacting the fixing piece 55. The neck portion 62 prevents the shank 232 of the fastener 23 from contacting the fixing piece 55 to decrease noise.

It is to be understood, however, that even though numerous characteristics and advantages of the present embodiments have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electronic device, comprising:
a chassis;
an electronic element fixed in the chassis, wherein a mounting hole is defined in a bottom edge of the electronic element;
a vibration dampening structure inserted in the mounting hole, wherein a through hole is defined in a center portion of the vibration dampening structure, the vibration dampening structure comprising a first dampening portion and a second dampening portion; and
a fastener inserted in the through hole of the vibration dampening structure to fix the electronic element in the chassis, the fastener comprising a head, wherein the first dampening portion prevents the head of the fastener from contacting the bottom edge of the electronic element, and the second dampening portion prevents the bottom edge from contacting the chassis.

2. The electronic device of claim 1, wherein the vibration dampening structure further comprises a neck portion connecting the first dampening portion to the second dampening portion; the through hole extends through the first dampening portion, the neck portion and the second dampening portion.

3. The electronic device of claim 2, wherein the mounting hole comprises a guiding portion capable of guiding the neck portion of the vibration dampening structure, and a receiving portion capable of receiving the neck portion; the neck portion has a thickness less than or equal to a thickness of the bottom edge.

4. The electronic device of claim 3, wherein a width of the guiding portion is smaller than a diameter of the receiving portion.

5. The electronic device of claim 3, wherein diameters of the first and second dampening portions are larger than an outer diameter of the receiving portion.

6. The electronic device of claim 1, wherein the vibration dampening structure is annular-shaped.

7. The vibration dampening structure of claim 1, wherein the vibration dampening structure is made of a rubber.

8. A vibration dampening structure for absorbing vibrations generated between an electronic device and a fastener, the vibration dampening structure comprising:
a first dampening portion configured for preventing a head of the fastener from contacting the electronic device;
a neck portion connected to the first dampening portion to isolate the fastener from the electronic device; and
wherein a through hole is defined in a center portion of the vibration dampening structure and extending through the first dampening portion and the neck portion for the fastener inserted therein.

9. The vibration dampening structure of claim 8, further comprising a second dampening portion connecting to the neck portion.

10. The vibration dampening structure of claim 8, wherein the vibration dampening structure is annular-shaped.

11. The vibration dampening structure of claim 8, wherein the vibration dampening structure is made of a rubber.
